(19) United States
(12) Patent Application Publication
(10) Pub. No.: US 2013/0295751 A1
(43) Pub. Date: Nov. 7, 2013

(54) THIN FILM FORMING DEVICE FOR SOLAR CELL AND THIN FILM FORMING METHOD

(71) Applicants: Takamasa Kato, Yamanashi (JP); Masaki Narushima, Yamanashi (JP); Kenichi Hara, Yamanashi (JP)

(72) Inventors: Takamasa Kato, Yamanashi (JP); Masaki Narushima, Yamanashi (JP); Kenichi Hara, Yamanashi (JP)

(73) Assignees: TOKYO ELECTRON LIMITED, Tokyo (JP); UNIVERSITY OF YAMANASHI, Yamanashi (JP)

(21) Appl. No.: 13/978,942

(22) PCT Filed: Jan. 13, 2012
(86) PCT No.: PCT/JP2012/050572

§ 371 Date: Jul. 10, 2013

(30) Foreign Application Priority Data
Jan. 13, 2011 (JP) 2011-005310
Dec. 20, 2011 (JP) 2011-278995

(51) Int. Cl. H01L 21/02

(52) U.S. Cl. CPC H01L 21/02617
USPC 438/478; 118/621; 118/712

(57) ABSTRACT

This thin film forming method for a solar cell forms a thin film that contains a plurality of elements on the surface of an object to be processed. A raw material solution that contains the elements is dispersed in a processing space and microparticles by an electric field, and the microparticles that are dispersed form a thin film that adheres to the surface of the object to be processed. Thus, a thin film for a solar cell element with preferable crystallinity can be formed even in an atmosphere at atmospheric pressure.

### TECHNICAL FIELD

The present invention relates to a thin film forming device and a thin film forming method for forming a thin film for use in a photoelectric conversion element such as, for example, a solar cell.

### BACKGROUND

In general, a photoelectric conversion element such as, for example, a solar cell uses an energy conversion characteristic of a semiconductor material. In particular, a solar cell receives attention as a means for obtaining electric energy without adversely affecting the global environment. A photoelectric conversion element of this type is configured by laminating various films for photoelectric conversion, for example, p-type semiconductor films or n-type semiconductor films over a plurality of layers on a surface of, for example, a silicon substrate using a vacuum film forming device such as, for example, a chemical vapor deposition (“CVD”) device.

When a vacuum film forming device is used, the quality of an obtained film is relatively good. However, devices or installations for manufacturing cost much. For this reason, in order to drastically cut device costs or installation costs, there has been newly proposed a film manufacturing method for obtaining a desired thin film by causing particles of a thin film material such as, for example, a metal oxide such as titanium oxide to be adhered to a surface of, for example, a film or a glass substrate through, for example, spraying or application of a solution formed by solving the particles in a solvent such as water or alcohols, and drying the solution by heat (see, e.g., Japanese Patent Laid-open Publication No. 2002-324591 and International Publication No. WO 2004/033756).

### DISCLOSURE OF THE INVENTION

### Problem to Be Solved by the Invention

However, there is a problem in that a semiconductor thin film formed through the film forming method using a simple spray coating or an application as described above is not so good in liquid crystallinity and thus, not good in a film property.

### Means to Solve the Problems

The present invention is to provide a thin film forming device and a thin film forming capable of forming a thin film for a photoelectric conversion element which is excellent in crystallinity even in an atmosphere at atmospheric pressure.

The present invention provides a thin film forming method of forming a thin film containing a plurality of elements for use in a solar cell on a surface of an object to be processed (“processed object”). The thin film forming method includes dispersing a raw material solution containing the elements in a processing space as microparticles by an electric field, and causing the dispersed microparticles to be adhered to the surface of the processed object to form the thin film.

Also, the present invention provides a thin film forming device for forming a thin film containing a plurality of elements for use in a solar cell on a surface of a processed object. The thin film forming device includes: a raw material solution supply unit configured to supply a raw material solution containing the elements to a processing space; a holding unit configured to hold processed object; a heating unit configured to heat the processed object; and an electric field power supply unit configured to apply a voltage between the holding unit and the raw material solution supply unit to disperse the raw material solution as microparticles by the electric field.

Further, the present invention provides a thin film forming device for forming a thin film containing a plurality of elements for use in a solar cell on surface of a processed object. The thin film device includes: a raw material solution supply unit configured to supply a raw material solution containing the elements to a processing space; a holding unit configured to hold processed object; a heating unit configured to heat the processed object; a draw-out electrode installed in the vicinity of the raw material solution supply unit; and a draw-out power supply unit configured to apply a voltage between the holding unit and the raw material solution supply unit to disperse the raw material solution as microparticles by the electric field.

### Effect of the Invention

According to the present invention, a raw material solution is dispersed by an electric field as microparticles to be adhered to a surface of a processed project to form a film. Therefore, a crystalline thin film which has an excellent characteristic of film quality may be formed.

### BRIEF DESCRIPTION OF THE DRAWINGS

FIG. 1 is a view illustrating a configuration of an example of a first exemplary embodiment of a thin film forming device of the present invention.

FIG. 2 is an enlarged view illustrating a nozzle of a raw material solution supply unit partially in cross-section.

FIGS. 3A to 3C are graphs illustrating evaluation results of CuInS₂ thin films.

FIGS. 4A and 4B are graphs illustrating evaluation results of an InSe containing films.

FIG. 5 illustrates electron micrographs of InSe containing films.

FIGS. 6A and 6B are graphs illustrating evaluation results of an InS containing films.

FIGS. 7A and 7B are graphs illustrating evaluation results of an InS containing films.

FIGS. 8A and 8B are graphs illustrating evaluation results of a CuZnSnS containing film.

FIGS. 9A and 9B are graphs illustrating evaluation results of a CuZnSnS containing film.

FIG. 10 is a view illustrating a first modified example of the header unit of the raw material solution supply unit.

FIG. 11 is a view illustrating a second modified example of the header unit of the raw material solution supply unit.

FIG. 12 is a view illustrating a third modified example of the header unit of the raw material solution supply unit.

FIG. 13 is a view illustrating a fourth modified example of the header unit of the raw material solution supply unit.

FIG. 14 is a view illustrating a fifth modified example of the header unit of the raw material solution supply unit.

FIG. 15 is a view illustrating a configuration of an example of a second exemplary embodiment of a thin film forming device of the present invention.

FIG. 16 is an enlarged view illustrating an area in the vicinity of the nozzle of the raw material solution supply unit partially in cross-section.

FIG. 17 is a partial enlarged view illustrating a modified example of the raw material solution supply unit and a draw-out electrode.

FIG. 18 is a schematic cross-sectional view illustrating examples of structures of photoelectric conversion elements.

### DETAILED DESCRIPTION TO EXECUTE THE INVENTION

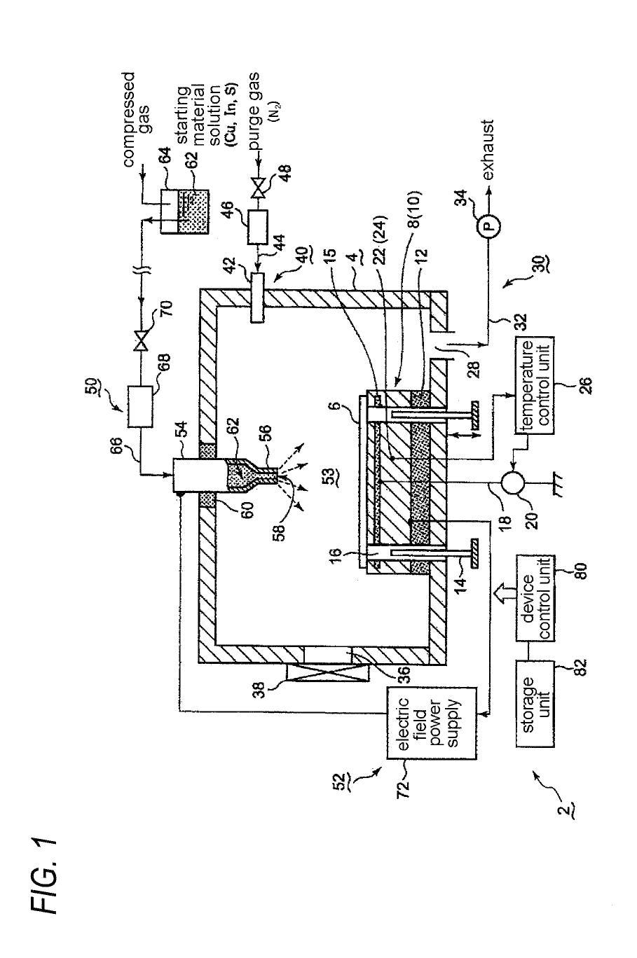

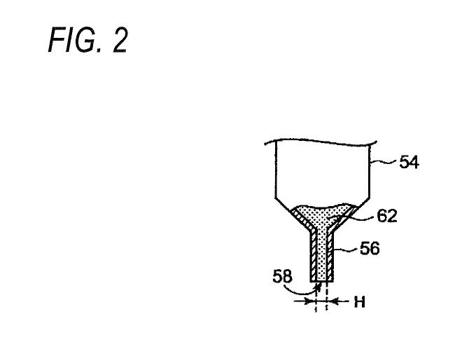

Hereinafter, exemplary embodiments of a thin film forming device and a thin film forming method for forming a thin film for use in a solar cell according to the present invention will be described in detail with reference to accompanying drawings. FIG. 1 is a view illustrating a configuration of an example of a thin film forming device according to a first exemplary embodiment of the present invention, and FIG. 2 is an enlarged view illustrating a nozzle of a raw material solution supply unit partially in cross-section. Here, a case of forming a thin film containing a plurality of elements will be described by way of an example. The thin film may be used in a photoelectric conversion element such as, for example, a solar cell.

### First Exemplary Embodiment

As illustrated in FIG. 1, the first exemplary embodiment of the thin film forming device 2 includes a processing container 4 formed in a box shape. Also, it is not required to especially provide the processing container 4 when a film forming processing of the thin film forming method of the present invention is performed in an atmosphere at atmospheric pressure. However, in order to exclude invasion of, for example, particles, it is desirable to provide the processing container 4. When the film forming processing is performed in an atmosphere at atmospheric pressure, the processing container 4 may be made of a low pressure-resistant material such as, for example, a thin resin plate made of, for example, a plastic, or a thin metal plate such as an aluminum plate or an aluminum alloy plate. Meanwhile, when the film forming processing is performed in a reduced pressure atmosphere (vacuum atmosphere), the processing container 4 is constituted with a sufficient press-resistant material such as, for example, a thick resin plate or a thick metal plate such as a thick aluminum plate or a thick aluminum alloy plate. Here, a case in which a metal plate is used as the material of the processing container 4 will be described by way of an example.

A holding unit 8 configured to hold a substrate 6 which is a processed object is provided on a bottom within the processing container 4. The substrate 6 is made of, for example, a glass plate or a resin plate. Here, a mounting table 10 is provided as the holding unit 8. The mounting table 10 is formed in a shape corresponding to the substrate 6. When the substrate 6 has a circular shape, the mounting table 10 is formed in the circular shape, and when the substrate 6 is has a rectangular shape, the mounting plate 10 is formed in the rectangular shape. In addition, the shape of the substrate 6 is optional.

The mounting table 10 is made of an electrically conductive metal such as, for example, aluminum or aluminum alloy and installed on the bottom of the container through an insulation member 12. A heating unit 15 configured to heat the substrate 6 is provided in the mounting table 10. As for the heating unit 15, a resistance heating heater such as, for example, a ceramic heater or a carbon wire heater is embedded in the mounting table 10 in an insulated state substantially over the entire mounting table 10.

The mounting table 10 is provided with lifter pins 14 configured to move up or down the substrate 6 at the time of carrying-in or carrying-out the substrate 6. Specifically, a pin insertion through-hole 16 extends in the vertical direction through the mounting table 10, the insulation member 12 and the bottom of the container, and the lifter pin 14 is inserted into the pin insertion through-hole 16 to be movable in the vertical direction. In addition, the lifter pin 14 is configured such that, when the lifter pin 14 is lifted by an actuator (not illustrated), the lifter pin 14 may be extended upward from the mounting table 10 or retracted to the mounting table 10 to raise or lower the substrate 6. Depending on the size of the substrate 6, a plurality of lifter pins 14 may be provided. Also, when the film forming processing is performed in a reduced pressure atmosphere, a retractable bellows (not illustrated) made of a metal may be installed at a portion of the bottom of the container penetrated by the lifter pin 14 to maintain the gas tightness of the inside of the processing container 4.

The heating unit 15 is configured to be connected to a heater power supply 20 through a power supply line 18 so that heating power may be supplied to the heating unit 15. In order to measure the temperature of the substrate 6, a temperature measuring unit 22 is provided. Specifically, the temperature measuring unit 22 may be constituted by a thermocouple 24 installed adjacent to the heating unit 15 in the mounting table 10 and the substrate 6 and configured to measure the temperature of the substrate 6. In addition, the temperature measuring unit 22 is connected to a temperature control unit 26 constituted with, for example, a computer, and the temperature control unit 26 is configured to adjust the output of the heater power supply 20 based on the measurement value by the thermocouple 24 so as to control the temperature of the substrate 6.

An exhaust port 28 is formed through the bottom of the processing container 4 and an exhaust system 30 is connected to the exhaust port 28 to exhaust the atmosphere within the processing container 4. Specifically, the exhaust system 30 includes an exhaust passage 32 connected to the exhaust port 28 and an exhaust pump 34 is installed in the middle of the exhaust passage to facilitate the exhaust. When the film forming processing is performed in an atmosphere at atmospheric pressure, the exhaust passage 32 may be directly connected to an exhaust duct that conducts the exhaust inside a factory without providing the exhaust pump 34. Further, when the film forming processing is performed in a reduced pressure atmosphere, a vacuum pump 34 may be used as the exhaust pump 34 and a pressure regulating valve (not illustrated) may be installed in the exhaust passage 32 upstream of the vacuum pump so as to enable the regulation of pressure within the processing container 4.

A substrate carrying-in/carrying-out hole 36 is formed on a side wall of the processing container 4 and an opening/closing door 38 is provided at the carrying-in/carrying-out hole 36. Also, when the film forming processing is performed in the reduced pressure atmosphere, a gate valve which is opened/closed in a gastight manner may be preferably used as the opening/closing door 38.

The processing container 4 is provided with a purging gas intake unit 40 configured to discharge a purging gas into the processing container 4. The purging gas intake unit 40 includes a gas nozzle 42 installed in a side wall of the processing container 4, and a gas passage 44 is connected to the gas nozzle 42. Further, a flow rate controller 46 such as a mass flow rate controller and an open/close valve 48 are sequentially installed in the gas passage 44 so as to supply a purging gas, for example, an N₂ gas in a controlled manner as desired. Besides N₂, a noble gas such as, for example, He or Ar may be used as the purging gas.

In addition, in a processing space 53 above the substrate 6 within the processing container 4, the processing container 4 is provided with a raw material solution supply unit 50 configured to supply a raw material solution that contains a plurality of elements which form a material of the thin film to be formed, and an electric field power supply unit 52 configured to apply voltage between the raw material solution supply unit 50 and the mounting table 10 which is the holding unit 8 to form an electric field in the processing space 53.

Specifically, the raw material solution supply unit 50 includes a header unit 54 configured to store the raw material solution temporarily. The header unit 54 is formed in a shape of a cylindrical body from an electrically conductive metallic material such as, for example, aluminum or aluminum alloy and attached to the ceiling portion of the container through an insulation member 60. Alternatively, the header unit 54 may be a dual structure cylinder of which the outer wall is formed from a metallic material and the inner wall is formed from, for example, a highly chemical-resistant glass or plastic. As illustrated in FIG. 2, the inner diameter of the header unit 54 is narrowed toward the front end of the header unit 54 and a nozzle 56 is provided at the front end. The nozzle 56 is formed, for example, in an elongated hollow cylindrical shape, and the lower end of the nozzle 56 forms a solution outlet 58. As described below, the raw material solution is dispersed downwardly from the solution outlet 58 as microparticles by an electric field.

Although the inner diameter H of the nozzle 56 may vary depending on the material, viscosity or density of the raw material solution or the installation direction of the nozzle 56, the inner diameter has a size in which the raw material solution does not drip as droplets, for example, in the range of about 0.1 mm to about 0.35 mm, preferably in the range of about 0.22 mm to about 0.26 mm. The nozzle 56 is also formed of an electrically conductive metallic material such as, for example, aluminum or aluminum alloy. Alternatively, the header unit 54 or the nozzle 56 may also be formed of a highly anti-corrosive and electrically conductive material, for example, PEEK (trademark).

A raw material passage 66 extending from a raw material storage tank 64 configured to store the raw material solution 62 is connected to the header unit 54 so that the raw material solution 62 may be pumped to the header unit 54 at a predetermined pressure by a compressed gas introduced into the raw material storage tank 64. In the middle of the raw material passage 66, a flow rate controller 68 such as a mass flow rate controller and an open/close valve 70 are sequentially provided so that the raw material solution 62 may be supplied to the header unit 54 while being controlled in flow rate as desired. Here, as for the raw material solution 62, a raw material solution that contains, for example, Cu, In and S as the elements is used and is adapted to form a CuInS₂ film as the semiconductor thin film.

The electric field power supply unit 52 is constituted with an electric field power supply 72 which is configured to be voltage-controllable. The electric field power supply 72 is configured to apply a voltage between the header unit 54 and the mounting table 10 located below the header unit 54 through a wiring 73 so as to form an electric filed in the processing space 53. The electric field power supply 72 may be configured to apply, for example, a direct current (DC) voltage or a pulse voltage. Also, the electric field power supply 72 may be configured to apply an alternating current (AC) voltage as long as the AC voltage has a frequency that enables the dispersion of the raw material solution 62. The electric field power supply unit 52 has a function of drawing-out the raw material solution 62 in the form of mist from the nozzle 56 to disperse the raw material solution 62 as microparticles and a function of accelerating the dispersed microparticles to the mounting table 10 side.

Here, the distance between the nozzle 56 and the substrate 6 may vary depending on the size of the substrate 6 without being especially limited. For example, when the diameter of the substrate 6 is about 10 cm, the distance may be in the range of about 10 cm to about 20 cm. Also, the output of the electric field power supply 72 is, for example, in the range of about 10 kV to about 30 kV.

The overall operation of the thin film forming device 2 is adapted to be controlled by a device control unit 80 constituted by, for example, a computer, and the program of the computer for executing the operation is stored in a storage medium 82. The storage medium 82 may be constituted by, for example, a flexible disc, a CD (Compact Disc), a hard disc, a flash memory, or a DVD. Specifically, for example, a control of process pressure (when film forming in a pressure-reduced atmosphere), a control of supply pressure and supply flow rate of the raw material solution 62, and a control of output voltage of the power supply for electric field 72 are conducted by an instruction from the device control unit 80. Here, the mounting table 10 and the header unit 54 are fixedly installed. However, they may be moved relatively or, for example, the mounting table 10 may be provided with a rotation mechanism (not illustrated) so that the rotation mechanism may the mounting table 10.

Next, descriptions will be made on a thin film forming method of the present invention which may be performed using the thin film forming device of the present invention configured as described above. First, the opening/closing door 38 installed on a side wall of the processing container 4 is opened, and a non-processed substrate 6 held on a transportation arm (not illustrated) is carried into the processing container 4 through the carrying-in/carrying-out hole 36. In addition, the lift pins 14 provided in the mounting table 10 which is a holding unit 8 are moved up and down so that the lift pins 14 are extended from or retracted to the top surface of the mounting table 10. Thus, the lifter pins 14 receive and place the substrate 6 on the mounting table 10.

Next, power is supplied from a heater power supply 20 to the heating unit 15 installed in the mounting table 10 to heat the entire mounting table 10, thereby heating the substrate 6 placed on the mounting table 10 to a predetermined process temperature and maintaining the substrate 6 at the temperature. Further, while causing N₂ gas as purging gas to flow within the processing container 4 from the introduction unit 40, the exhaust pump 34 of the exhaust system 30 is also driven to exhaust the atmosphere within the processing container 4 such as gas generated at the time of film forming. Here, since the film forming processing is performed, for example, in an atmosphere at atmospheric pressure, the exhaust pump 34 does not need to exhaust the atmosphere so strongly.

Also, the raw material solution supply unit 50 is driven to pump the raw material solution 62 from the raw material storage tank 64 and supply the raw material solution 62 to the header unit 54 while controlling the flow rate thereof. At the same time, the electric field power supply 72 of the electric field power supply unit 52 is operated to apply, for example, a direct current voltage between the header unit 54 and the nozzle 56 and the mounting table 10, thereby generating an electric field in the processing space 53. Thus, the raw material flowing out a little bit from the solution outlet 58 at the lower end of the nozzle 56 of the header unit 54 is drawn into the electric field to become microparticles which are dispersed in the form of mist. The microparticles are electrically charged and accelerated toward the mounting table 10 which is the opposite side electrode, and fall down in a spry form on the surface of the mounting table 10, i.e., on the surface of the substrate 6.

As a result, the microparticles of the raw material solution 62 are adhered to the surface of the substrate in the form of a film and the atoms of the raw material are moved on the surface of the substrate 6 by being heated, thereby forming a crystal semiconductor thin film. Such a film forming method is referred to as an electrostatic spray method.

<Formation of CuInS₂ Thin Film>

The raw material solution used herein may be formed by solving, for example, chlorides of elements that constitute the thin film in a solvent. Specifically, when forming a semiconductor thin film formed by CuInS₂ as the thin film, for example, CuCl₂ which is a chloride of the element Cu (cupper), InCl₃ which is a chloride of the element In (indium), and thiourea (SC(NH₂)₂) which is a compound of the element S (sulfur) are mixed and solved in a solvent, thereby forming the raw material solution 62. Here, for example, ethanol of alcohols may be used as the solvent.

The process pressure is set to substantially the atmospheric pressure here but is not limited to this. As described above, film forming may be performed in a reduced pressure atmosphere (vacuum atmosphere). The temperature of the substrate 6 is in the range of 250° C. to 305° C. When the temperature is lower than 250° C., energy is insufficient to crystallize the thin film and when the temperature is higher than 305° C., the sulfur (S) in the thin film is vaporized. Thus, the crystal film may not be formed.

In addition, the atomic ratio of “Cu” and “In” in the raw material solution 62, Cu/In, is set to a value in the range of 0.85 to 1.40. When the atomic ratio is smaller than 0.85 or larger than 1.40, a crystal thin film with a target energy gap may not be fabricated. By changing the atomic ratio, Cu/In, it is possible to control the conductivity type of the formed semiconductor thin film. As described in detail below, for example, when the atomic ratio, Cu/In, is not more than 1, the thin film becomes an n-type semiconductor and when the atomic ratio is more than 1, the thin film becomes a p-type semiconductor. Lack of sulfur may inhibit the formation of a crystalline thin film. However, even if the sulfur is added excessively, no particular problem will be caused because the sulfur is vaporized during the film forming. Accordingly, it is preferable to add sulfur in an atomic ratio of, for example, 1.5 to 5 times of Cu or In.

The strength of the electric field formed in the processing space 53 is set to preferably 100 kV/m or more. When the electric field is lower than this value, the raw material solution 62 may not be sufficiently dispersed in the form of mist. Thus, a thin film may not be formed. Since the film forming is conducted by dispersing the raw material solution as microparticles by the electric field so that the microparticles may be adhered to a surface of an object, a crystalline thin film with an excellent quality may be formed. In particular, when the film forming processing is conducted at the atmospheric pressure, it is not required to configure the thin film forming device itself in a vacuum-resistant specification, thereby substantially reducing the device costs and the installation costs.

<Evaluation of CuInS₂ Thin Film>

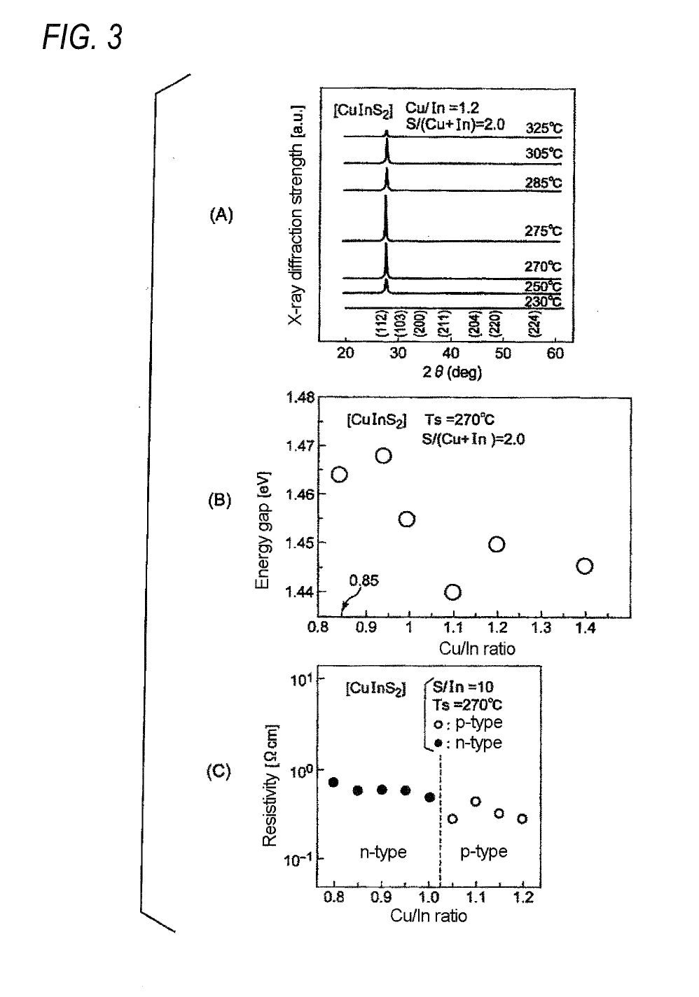

A CuInS₂ thin film was formed using a raw material solution in a mixed state in which “Cu”, “In” and “S” are contained therein as described above, and practically using the apparatus as illustrated in FIGS. 1 and 2 and various properties were evaluated. The evaluation results will be described with reference to FIG. 3. FIG. 3 illustrates graphs that show the evaluation results of the CuInS₂ thin film, in which FIG. 3A is a graph illustrating a relation of substrate temperature at the time of film forming and X-ray diffraction strength, FIG. 3B is a graph illustrating a relation of atomic ratio, Cu/In, and energy gap, and FIG. 3C is a graph illustrating a relation of atomic ratio, Cu/In, conductivity type and resistivity. Here, as for the raw material, CuCl₂ which is a chloride of Cu, InCl₃ which is a chloride of In, and thiourea which is a compound of sulfur (S) were used, and the raw material solution was fabricated by solving these materials in ethanol.

First, CuInS₂ thin films were fabricated while changing the substrate temperature at the time of film forming from 230° C. to 325° C. The atomic ratio, Cu/In, in the raw material solution at this time was “1.2” and the atomic ratio of sulfur, S/(Cu+In), was set to “2.0”. The thin films formed at this time were analyzed using an X-ray diffraction device and the results are represented in FIG. 3A. In FIG. 3A, crystal planes are indicated within parentheses along the horizontal axis.

As illustrated in FIG. 3A, when the substrate temperature is 230° C., the X-ray peak is barely visible. Thus, it may be seen that the thin film is hardly crystallized. Also, when the substrate temperature is 325° C., the X-ray peak is visible at the crystal plane (112). However, since the X-ray peak is too small, it cannot be determined that it is sufficient. In comparison, when the substrate temperature is in the range of 250° C. to 305° C., all the thin films show a high X-ray peak at the crystal plane (112). Thus, it may be seen that preferable semiconductor crystal films are formed.

Next, energy gaps of thin films as being formed were measured while variously changing the atomic ratio, Cu/In, in the raw material solution 62. Here, the atomic ratio, Cu/In, was changed from 0.8 to 1.5. At that time, the substrate temperature Ts was 270° C. and the atomic ratio of sulfur, S/(Cu+In), was set to “2.0”. The results are represented in FIG. 3B. In FIG. 3B, the horizontal axis represents the atomic ratio, Cu/In, and the vertical axis represents the energy gap.

As illustrated in FIG. 3B, when the atomic ratio Cu/In is in the range of 0.85 to 1.40, the energy gap is included in the range of 1.44 eV to 1.47 eV. Thus, it may be seen that the property as a crystal film is excellent. In comparison, when the atomic ratio Cu/In is 0.8 and 1.5, no energy gap occurs (no value is indicated in the graph). Thus, it may be seen that the property in film quality is poor.

Next, measurements were made on the resistivity and conductivity type of semiconductor of thin films formed while variously changing the atomic ratio, Cu/In in the raw material solution. The atomic ratio, Cu/In, was changed from 0.8 to 1.2. At that time, the substrate temperature Ts was 270° C., and the atomic ratio of sulfur, S/In, was set to “10”. The results are represented in FIG. 3C. In FIG. 3C, the horizontal axis represents atomic ratio, Cu/In, and the vertical axis represents resistivity.

As apparent from FIG. 3C, regarding the resistivity, it may be seen that all the films are in the range 10⁻¹to 10⁰ Ωcm and thus excellent. Also, it may be seen that when the atomic ratio, Cu/In, is 1 or less, the conductivity type of formed semiconductor thin films is n-type, and when the atomic ratio, Cu/In, is larger than 1, the conductivity type is p-type. Thus, it may be seen that the conductivity type of a semiconductor thin film as being formed may be freely controlled by adjusting the atomic ratio, Cu/In. In addition, an n-type CuInS₂(Sn, Zn, Ge) film may be formed by doping, for example, Sn, Zn or Ge on the thin film.

<Evaluation of γ-In₂Se₃ Thin Film>

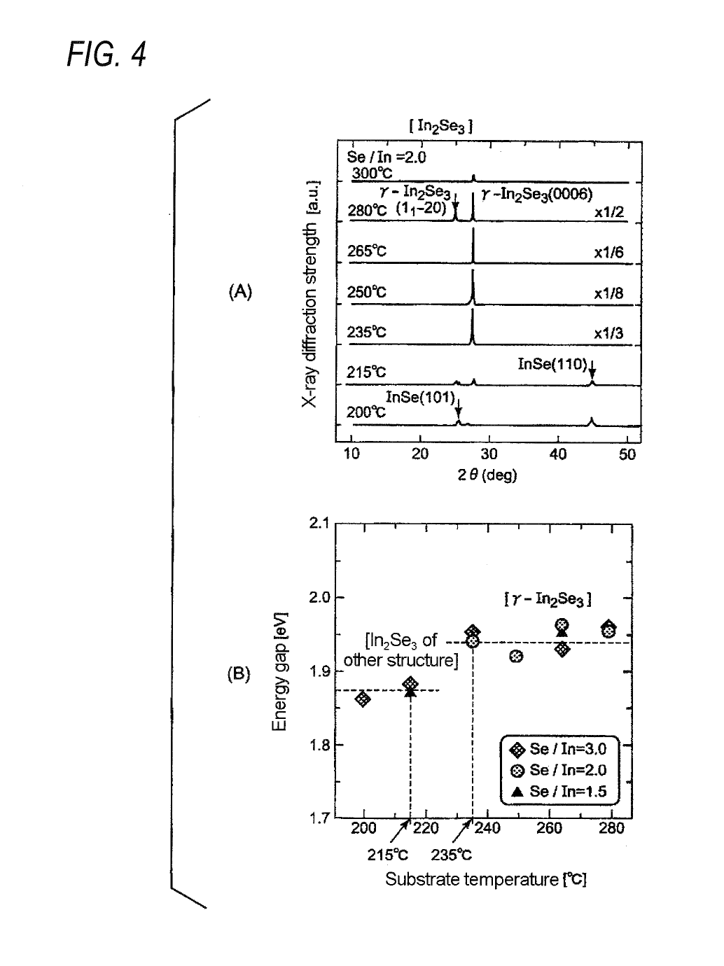

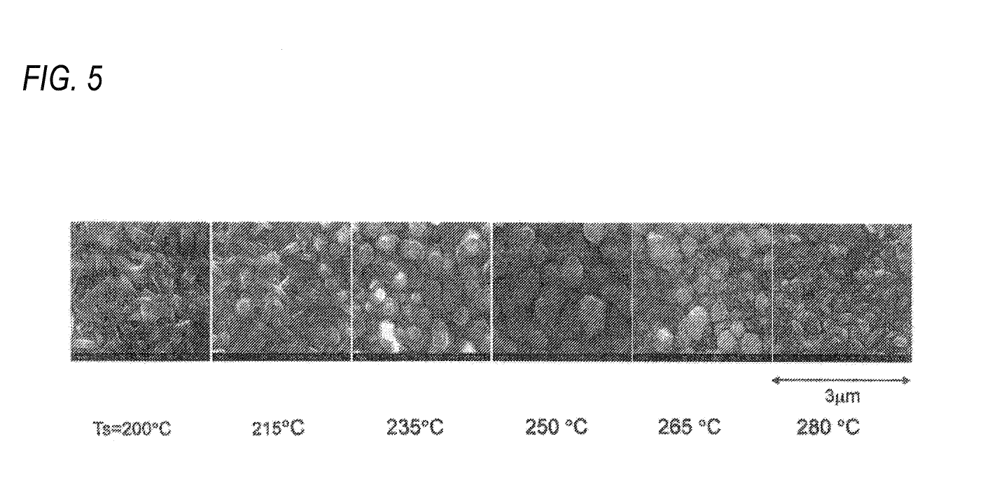

Next, semiconductor thin films were fabricated by an In₂Se₃ film instead of the above mentioned CuInS₂ film and practically using the apparatus as illustrated FIGS. 1 and 2 and various properties were measured. The evaluation results will be described with reference to FIGS. 4 and 5.

FIGS. 4A and 4B are graphs illustrating the evaluation results of InSe containing films in which FIG. 4A represents a relation of substrate temperature at the time of film forming and X-ray diffraction strength, and FIG. 4B represents a relation between substrate temperature at the time of film forming and energy gap. FIG. 5 illustrates electron micrographs of InSe containing films.

Here, a raw material solution was prepared by using InCl₃ which is a chloride of In and N—N dimethyl selenourea (C₃H₈N₂Se) which is a compound of Se as raw materials and solving them in ethanol. First, InSe containing films were fabricated while changing the substrate temperature at the time of film forming from 200° C. to 300° C. The atomic ratio, Se/In, in the raw material solution was set to “2.0”. The thin films as being formed were analyzed using an X-ray diffraction device and the results are represented in FIG. 4A. In FIG. 4A, crystal planes are indicated after InSe containing films, respectively, and magnifications of X-ray peak values are described at the right side of the graph.

As apparent from the graph illustrated in FIG. 4A, when the substrate temperature is 200° C., an InSe film with crystal planes of (101) and (110) was formed which is not a target thin film. Also, when the substrate temperature is 215° C., an InSe film with crystal planes of (101) and (110) was formed which is not a target thin film. In addition, when the substrate temperature is 300° C., a γ-In₂Se₃ film (0006) was formed which is a target thin film. However, the film was too small and thus is not sufficient in crystallinity.

In comparison, it may be seen that when the substrate temperature is in the range of 235° C. to 280° C., a target γ-In₂Se₃ film (0006) is sufficiently crystallized and formed on all the substrates and thus exhibits an excellent characteristic result. Also, the conductivity type of the γ-In₂Se₃ film was n-type. In such a case, it may be seen that the substrate temperature in the range of 250° C. to 265° C. is particularly preferable since the X-ray peak value is high.

FIG. 5 illustrates electron micrographs when film forming was performed at a substrate temperature in the range of 200° C. to 280° C. In particular, it may be seen that when the substrate temperature is 250° C. and 265° C. which are included in the most preferable substrate temperature range, hexagonal shapes are clearly and obviously visible which is a characteristic of γ-In₂Se₃ crystals of the hexagonal system.

Next, characteristics of quality of films were measured for the films fabricated when the substrate temperature at the time of film forming was changed while changing, variously the atomic ratio of In and Se. The results are represented in FIG. 4B. Here, the atomic ratio of Se and In, Se/In, is changed variously to “1.5,” “2.0” and “3.0”. As apparent from the graph illustrated in FIG. 4B, when the substrate temperature is lower than 215° C., the energy gap is about 1.87 eV and an In₂Se₃ film which is not a target structure was formed. In comparison, when the substrate temperature is 235° C. to 280° C. (data at 300° C. does not exist), it may be seen that since the energy gap is about 1.95 eV and a targeted γ-In₂Se₃ is formed regardless of the value of the atomic ratio, Se/In, excellent results may be obtained. The conductivity type of the γ-In₂Se₃ was n-type.

With respect to the conductive films of the γ-In₂Se₃ crystal films formed as described above, an annealing processing was performed after film forming. As a result, it was possible to control the conductivity type of the conductive films. That is, as described above, the conductivity type of the γ-In₂Se₃ crystal films formed as described above was n-type. When the annealing temperature is lower than 320° C., the n-type was maintained. However, when the annealing temperature was set to 320° C. or higher, it was possible to change the conductivity type from n-type to p-type. Thus, in order to maintain the conductivity type of n-type after the semiconductor films of the γ-In₂Se₃ crystal films are produced, the annealing processing may not be performed or may be performed at a predetermined temperature, for example, at a temperature lower than 320° C. In order to change the conductivity type to p-type, the annealing may be performed at a predetermined temperature, for example, at a temperature of 320° C. or higher. Consequently, it may be seen that the conductivity type is freely selectable. In other words, it is possible to select the conductivity type of the semiconductor film by performing a temperature-controlled annealing processing.

<Evaluation of In₂5₃ Thin Film>

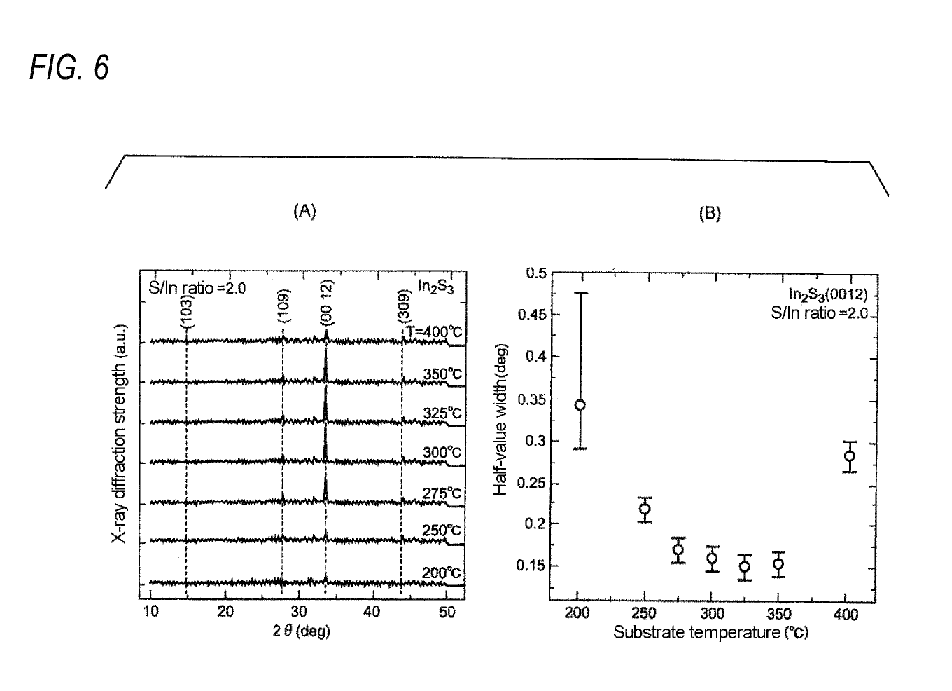

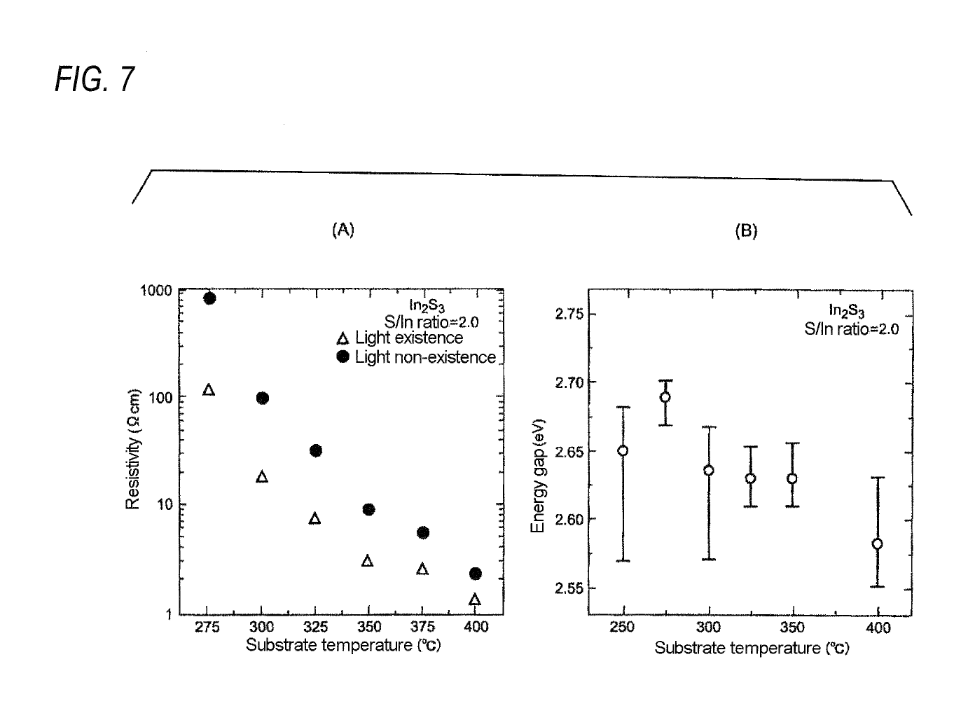

Next, semiconductor thin films made of an In₂S₃ film were fabricated practically using the apparatus illustrated in FIGS. 1 and 2 and various properties were measured. The evaluation results will be described with reference to FIGS. 6 and 7. FIGS. 6 and 7 are graphs illustrating evaluation results of InS containing films. FIG. 6A is a graph illustrating a relation of substrate temperature at the time of film forming and X-ray diffraction strength and FIG. 6B is a graph illustrating a relation of substrate temperature and half-value width of X-ray spectrum. In addition, FIG. 7A is a graph illustrating a relation of substrate temperature at the time of film forming and resistivity and FIG. 7B is a graph illustrating a relation of substrate temperature at the time of film forming and energy gap.

Here, CuCl₂ which is a chloride of Cu, InCl₃ which is a chloride of In and thiourea which is a compound of S were used as raw materials, and a raw material solution was fabricated by solving these materials in ethanol. Here, the process pressure was set to about atmospheric pressure. First, In₂S₃ thin films were fabricated while changing the substrate temperature at the time of film forming from 200° C. to 400° C. The atomic ratio, S/In, in the raw material solution at this time was set to “2.0”. The thin films formed at this time were analyzed using an X-ray diffraction device and the results are represented in FIG. 6A. In FIG. 6A, crystal planes are also indicated.

As illustrated in FIG. 6A, when the substrate temperature is 200° C., the X-ray peak is barely visible. Thus, it may be seen that an In₂S₃ thin film is hardly formed. Also, when the substrate temperature is 400° C., the X-ray peak is visible at the crystal plane (0012). However, since the X-ray peak is too small, it cannot be determined that it is sufficient.

In comparison, when the substrate temperature is in the range of 275° C. to 350° C., all the thin films show a high X-ray peak at the crystal plane (0012). Thus, it may be seen that preferable semiconductor crystal films are formed. In addition, half value widths of X-ray spectrums at the time of X-ray diffraction were obtained and the results are represented in FIG. 6B. As illustrated in FIG. 6B, when the substrate temperature is 200° C., 250° C. or 400° C., the half value width is large and is not excellent. In comparison, it may be seen that when the substrate temperature is in the range of 275° C. to 350° C., the half value widths are small and thus, the crystallinity is excellent. In particular, when the substrate temperature is in the range of 300° C. to 350° C., since the half value widths are small, the crystallinity is excellent. As a result, it may be seen that when forming the In₂S₃ thin films, the substrate temperature may be set to a temperature in the range of 275° C. to 350° C., preferably in the range of 300° C. to 350° C.

For the purpose of confirmation, the resistivity and energy gap of the InS containing thin films were measured and the results are represented in FIGS. 7A and 7B. The resistivity measurements were conducted for the thin films which were subject to light irradiation and for the thin films which were not subject to light irradiation. As illustrated in FIG. 7A, it may be seen that as the film forming temperature rises from 275° C. to 400° C., the resistivity gradually decreases, and the resistivity in the thin films which were subject to the light irradiation is lowered as compared to that in the thin films which were not subject to light irradiation.

From these results, it was confirmed that when light irradiation is conducted, holes are produced and at the same time, electrons flow. In addition, when the substrate temperature is 400° C., the resistivity was considerably reduced. It is estimated that sulfur was excessively released by heating. In addition, as illustrated in FIG. 7B, with respect to energy gap, it may be seen that since the measured value of the energy gap of each thin film is approximately close to the theoretical value of In₂S₃, 2.64 eV, each thin film has an approximately proper energy gab regardless of the film forming temperature. Also, when the substrate temperature is 275° C., the energy gap is about 2.68 eV, and when the substrate temperature is 400° C., the energy gap is about 2.57 eV. However, it is believed that the differences of these two cases from the theoretical value are within the margin of measurement error.

<Evaluation of Cu₂ZnSnS₄ Thin Film>

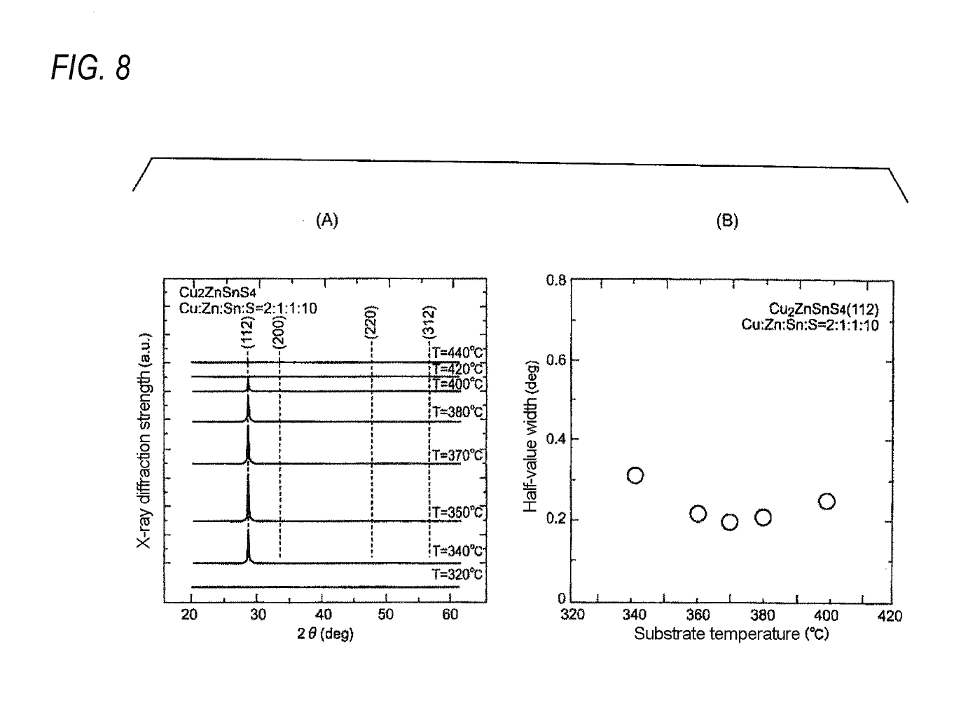

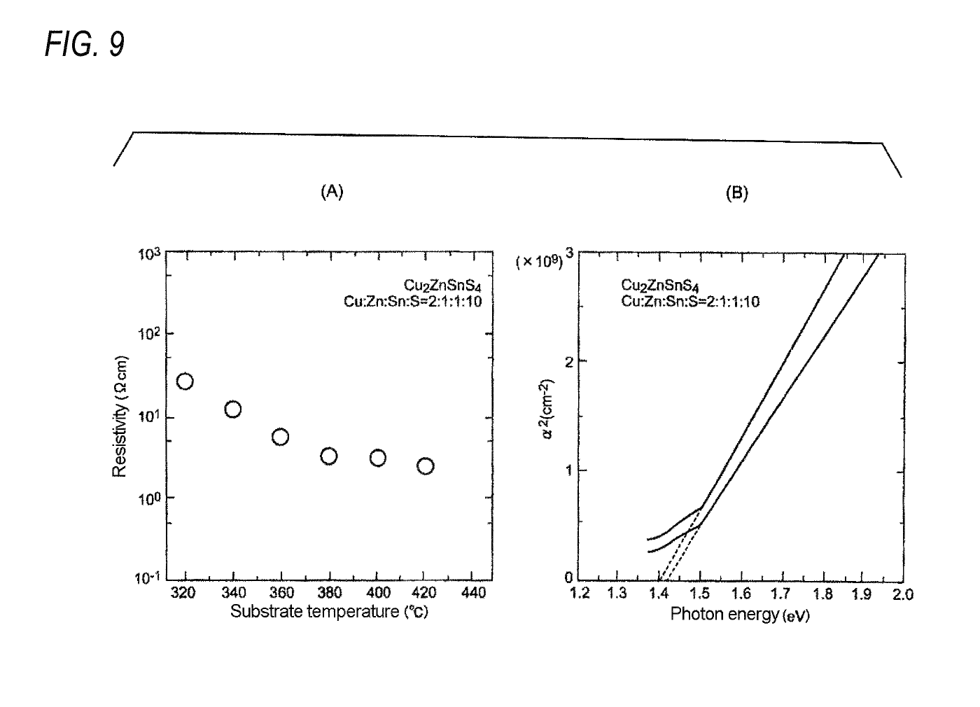

Next, semiconductor thin film made of a Cu₂ZnSnS₄ film were fabricated practically using the apparatus illustrated in FIGS. 1 and 2 and various properties were measured. The evaluation results will be described with reference to FIGS. 8 and 9. FIGS. 8 and 9 are graphs illustrating the evaluation results of CuZnSnS containing films. FIG. 8A is a graph illustrating a relation of substrate temperature at the time of film forming and X-ray diffraction strength and FIG. 8B is a graph illustrating a relation of substrate temperature and half value width of X-ray spectrum. FIG. 9A is a graph illustrating a relation of substrate temperature and resistivity and FIG. 9B is a graph illustrating a status when an energy gap is calculated from a relation of a light energy and a light absorption coefficient of a thin film.

Here, as described above, a raw material solution was prepared by using CuCl₃ which is a chloride of Cu, ZnCl₂ which is a chloride of Zn, SnCl₂ which is a chloride of Sn, and thiourea which is a compound of S as raw materials and mixing and solving the raw materials in a solvent (ethyl alcohol). The film forming process was conducted in the atmosphere. First, Cu₂ZnSnS₄ thin films were fabricated while changing the substrate temperature at the time of film forming from 320° C. to 440° C. The atomic ratio in the raw material solution was set to be “Cu:Zn:Sn:S=2:1:1:10.” The results obtained by analyzing the thin films formed at this time using an X-ray diffraction device are represented in FIG. 8A. In FIG. 8A, crystal planes are also indicated.

As illustrated in FIG. 8A, when the substrate temperature is 320° C. or in the range of 420° C. to 440° C., the X-ray peaks are barely visible. Thus, it may be seen that the Cu₂ZnSnS₄ thin films were hardly formed. Also, when the substrate temperature is 400° C., the X-ray peak is visible at the crystal plane (112). However, since the X-ray peak is too small, it cannot be determined that it is sufficient.

In comparison, that when the substrate temperature is in the range of 340° C. to 380° C., all the thin films show a high X-ray peak at the crystal plane (112), and in particular, when the substrate temperature is in the range of 360° C. to 370° C., the X-ray peak appears especially strongly. Thus, it may be seen that preferable semiconductor films were formed. In addition, the half value widths of X-ray spectrums at the time of X-ray diffraction were calculated and the results are represented in FIG. 8B. As illustrated in FIG. 8B, when the substrate temperature is 340° C. or 400° C., it is not so preferable since the half value width is large. In comparison, when the substrate temperature is in the range of 360° C. to 370° C., it may be seen that crystallinity is good since the half value widths are small. As a result, when forming the Cu₂ZnSnS₄ thin films, the substrate temperature may be set in the range of 340° C. to 380° C., more preferably 340° C. to 380° C.

For confirmation, the resistivity and energy gap of the CuZnSnS containing thin films were measured and the results are represented in FIGS. 9A and 9B. The measurement of resistivity was also conducted for the thin films which were not subject to light irradiation. As illustrated in FIG. 9A, it may be seen that as the film forming temperature rises from 320° C. to 420° C., the resistivity is gradually reduced.

In addition, when the substrate temperature is 400° C. or 420° C., the resistivity is considerably reduced. It is estimated that sulfur is released by heating and sulfur vacancies act as a donor. Further, as illustrated in FIG. 9B, with respect to the energy gap, it may be seen that since the measured value of the energy gap of each thin film is approximately close to the theoretical value of Cu₂ZnSnS₄, 1.40 eV, each thin film has an approximately proper energy gab regardless of the film forming temperature. In FIG. 9A, “α” indicates a light absorption coefficient and the energy gap is calculated based on the relation of the frequency of the light irradiated to a thin film and the light absorption coefficient α.

### First Modified Exemplary Embodiment of Raw Material Solution Supply Unit

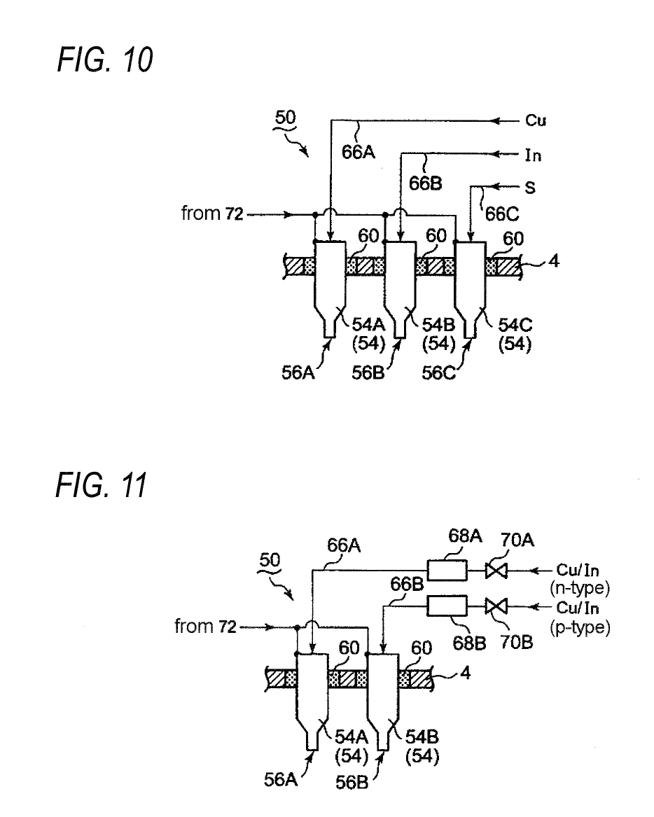

Next, the first modified exemplary embodiment of the raw material solution supply unit will be described. The above described exemplary embodiments use a single raw material solution that contains all the elements to be included in a thin film to be formed but is not limited to this. Plural kinds of raw material solutions may be used in each of which each elements to be included in the thin film to be formed is separately solved. Also, some, but not all, of elements to be included in the thin film to be formed may be contained in a single raw material solution. In such a case, the raw material solution supply unit is configured to be provided with a plurality of header units of which the number corresponds to the number of the kinds of the raw material solutions. FIG. 10 illustrates the first modified exemplary embodiment of the header units of the raw material solution supply unit. In FIG. 10, the constitutional components which are the same with those illustrated in FIGS. 1 and 2 will be denoted by the same reference numerals and the components not illustrated in FIG. 10 are configured to be the same with those illustrated in FIGS. 1 and 2.

As illustrated in FIG. 10, the raw material solution supply unit 50 is provided with a plurality of header units 54 (in the illustrated example, three header units 54A, 54B, 54C), and the header units 54A, 54B, 54C are connected with raw material passages 66A, 66B, 66C, respectively. The raw material passages 66A, 64B, 66C are configured to supply different raw material solutions, respectively, while controlling the flow rates thereof and to disperse each of the raw material solutions in the form of mist by electric field from the nozzles 56A, 56B, 56C.

In such a case, for example, a raw material solution formed by solving CuCl₂ in a solvent (ethanol) is caused to flow in the raw material passage 66A, a raw material solution formed by solving InCl₃ in a solvent (ethanol) is caused to flow in the raw material passage 66B, and a raw material solution formed by solving thiourea in a solvent (ethanol) is caused to flow in the raw material solution 66C. Here, the control of each atomic ratio may be achieved by controlling the supply amount of each raw material solution separately. The present modified exemplary embodiment may exhibit the same acting effects with those of the above described exemplary embodiments.

### Second Modified Exemplary Embodiment of Raw Material Solution Supply Unit

Next, the second modified exemplary embodiment of the raw material solution supply unit will be described. In the film forming method of CuInS₂ films as described above, only a single material solution in which the atomic ratio, Cu/In, is specifically defined, is used in the thin film forming device and thus, thin films of only one conductivity type of p-type or n-type may be formed in one film forming process (See, e.g., FIG. 3C). Here, a plurality of header units are provided to be supplied with raw material solutions of different atomic ratios, respectively, in such a manner that the raw material solutions may be switchingly supplied, which enables formation of a p-type thin film and an n-type thin film in succession in a single film forming process.

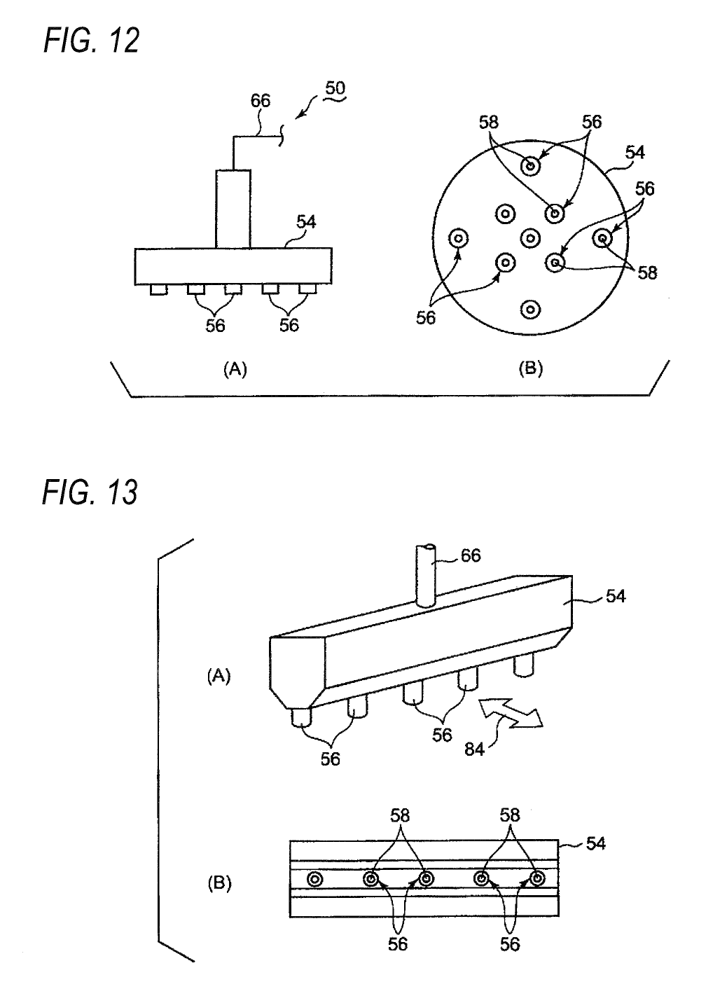

FIG. 12 illustrates the second exemplary embodiment of the header units of the raw material solution supply unit. In FIG. 11, the constitutional components which are the same with those illustrated in FIGS. 1 and 2 will be denoted by the same reference numerals and the components not illustrated in FIG. 11 are configured to be the same with those illustrated in FIGS. 1 and 2.

As illustrated in FIG. 11, as is the first modified exemplary embodiment illustrated in FIG. 10, the raw material solution supply unit 50 is provided with a plurality of header units 54 (in the illustrated example, two header units 54A, 54B), and the header units 54A, 54B, 54C are connected with raw material passages 66A, 66B, respectively. The raw material passages 66A, 64B are configured to supply different raw material solutions while controlling the flow rates thereof, respectively, and to selectively disperse the raw material solutions in the form of mist by electric field from the nozzles 56A, 56B, 56C. Here, opening/closing valves 70A, 70B each of which is installed at one of the raw material passages 66A, 66B are switched to selectively disperse each of the raw material solutions.

In the present modified exemplary embodiment, for example, a raw material solution (containing S) in which the atomic ratio, Cu/In, is adjusted so that an n-type semiconductor thin film may be formed is caused to flow in the raw material passage 66A, a raw material solution (containing S) in which the atomic ratio, Cu/In, is adjusted so that a p-type semiconductor thin film may be formed is caused to flow in the raw material passage 66B, and both the raw material solutions are selectively supplied to the processing space. As a result, an n-type CuInS₂ thin film and a p-type CuInS₂ thin film may be formed selectively and successively. The present modified exemplary embodiment may also exhibit the same acting effects with those of the above described exemplary embodiments.

### Third Modified Exemplary Embodiment of Raw Material Solution Supply Unit

Next, the third modified exemplary embodiment of the raw material solution supply unit will be described. In the raw material solution supply units 30 described above, each header unit 54 is provided with one nozzle but is not limited thereto. One header unit 54 may be provided with a plurality of nozzles. FIG. 12 illustrates the third exemplary embodiment of such header units of the raw material solution supply unit, in which FIG. 12A illustrates a front view and FIG. 12B illustrate a bottom view. In FIG. 12, the constitutional components which are the same with those illustrated in FIGS. 1 and 2 will be denoted by the same reference numerals and the components not illustrated in FIG. 12 are configured to be the same with those illustrated in FIGS. 1 and 2.

As illustrated in FIG. 12, the header unit 54 of the raw material solution supply unit 50 is formed in a hollow disc shape and nozzles 56 are provided substantially over the entire bottom surface side thereof. The header unit 54 may be preferably used when a processed substrate 6 has a circular shape, and allow the raw material solution in the form of mist to be uniformly adhered to the entire surface of the substrate 6, thereby improving the in-plane uniformity of the thickness of a formed thin film. When a processed substrate has a polygonal shape, a header unit 54 having a hollow polygonal shape which is the same with that of the substrate may be used.

### Fourth Modified Exemplary Embodiment of Raw Material Solution Supply Unit

The header unit 54 is formed in a hollow disc shape in the third modified exemplary embodiment described above but not limited thereto and may be configured as in the fourth exemplary embodiment as illustrated in FIG. 13. FIG. 13A illustrates a perspective view and FIG. 13B illustrate a bottom view. In FIG. 13, the constitutional components which are the same with those illustrated in FIGS. 1 and 2 will be denoted by the same reference numerals and the components not illustrated in FIG. 13 are configured to be the same with those illustrated in FIGS. 1 and 2.

As illustrated in FIG. 13, the header unit 54 is formed to be elongated in the transverse direction and formed substantially in a pentagonal cross-section aside from the lower end portion. In addition, a plurality of nozzles 56 are formed on the bottom portion of the header unit 54 at substantially equidistant intervals in the longitudinal direction.

Such a header unit 54 is effective when the substrate 6 is formed in a rectangular shape which is long in the transverse direction. For example, when the header unit and the substrate are adapted to be relatively moved and the header unit 54 is moved by a scanner mechanism (not illustrated) in a direction indicated by arrow 84 (in the longitudinal direction of the substrate) which is orthogonal to the longitudinal direction of the header unit, a film forming processing may be efficiently performed.

### Fifth Modified Exemplary Embodiment of Raw Material Solution Supply Unit

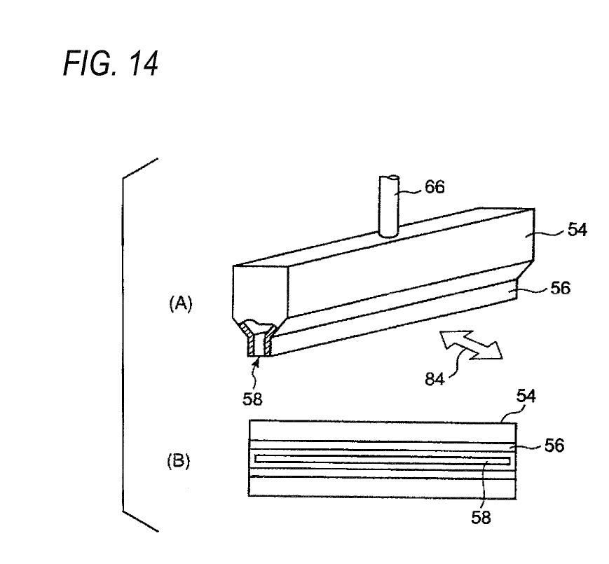

In the fourth modified exemplary embodiment, a plurality of nozzles 56 of a circular cross-section are formed on the bottom portion of the header unit 54 but are not limited to this. A nozzle may be configured as in the fifth modified exemplary embodiment as illustrated in FIG. 14. FIG. 14A illustrates a perspective view and FIG. 14B illustrate a bottom view. In FIG. 14, the constitutional components which are the same with those illustrated in FIGS. 1 and 2 will be denoted by the same reference numerals and the components not illustrated in FIG. 14 are configured to be the same with those illustrated in FIGS. 1 and 2.

As illustrated in FIG. 14, the header unit 54 is formed to be elongated in the transverse direction as in the fourth modified exemplary embodiment and formed substantially in a pentagonal cross-section aside from the lower end portion. In addition, a nozzle 56 having an elongated slit-like solution outlet 58 along the longitudinal direction thereof is formed on the bottom portion of the header unit 54 along the longitudinal direction of the header unit 54. Also, the raw material solution is adapted to be dispersed by electric field from the elongated slit-like solution outlet 58.

Such a header unit 54 is effective when the substrate 6 is formed in a rectangular shape which is long in the transverse direction as in the fourth modified exemplary embodiment. For example, when the header unit and the substrate are adapted to be relatively moved and the header unit 54 is moved by a scanner mechanism (not illustrated) in a direction indicated by arrow 84 (in the longitudinal direction of the substrate) which is orthogonal to the longitudinal direction of the header unit, a film fanning processing may be efficiently performed.

### Second Exemplary Embodiment of Thin Film Fanning Device

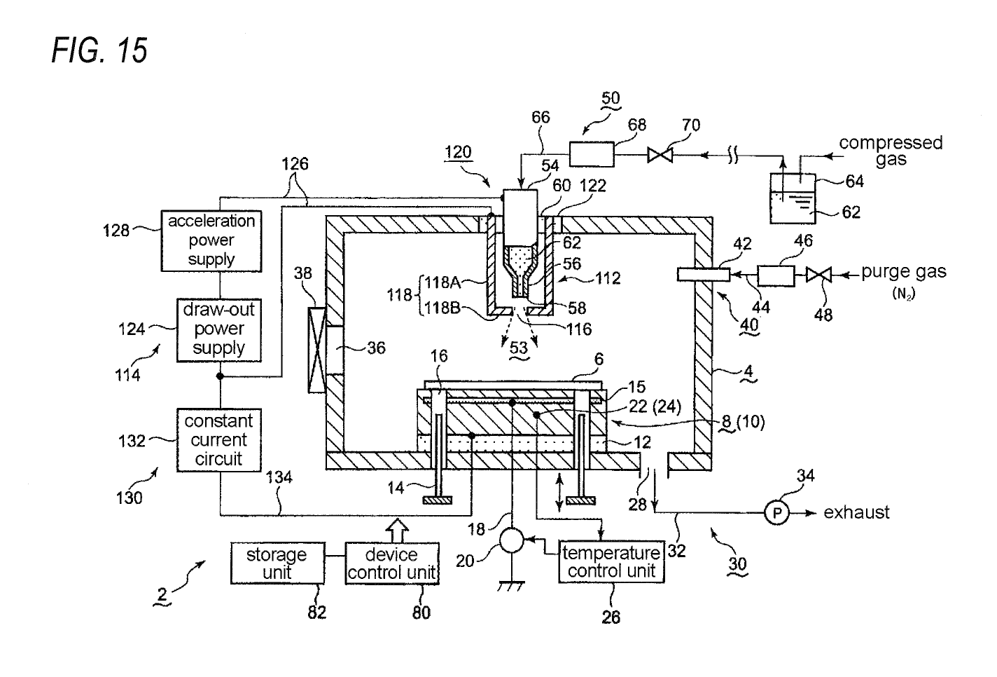

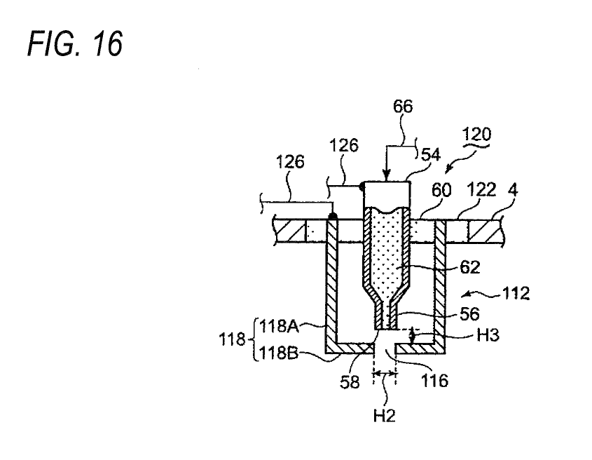

Next, the second exemplary embodiment of the thin film fanning device according to the present invention will be described. FIG. 15 is a configurational view illustrating an example of the second exemplary embodiment of the thin film forming device according to the present invention and FIG. 16 is an enlarged view illustrating the raw material solution supply unit in the vicinity of the nozzle partially in cross-section. The constitutional components which are the same with those illustrated in FIGS. 1 and 2 are denoted by the same reference numerals and the descriptions thereof will be omitted.

In the thin film forming device described above with reference, for example, FIG. 1, the raw material solution is drawn out as microparticles in the form of mist and accelerated by applying high voltage between the nozzle 56 at the lower end of the header unit 54 and the holding unit 8 to form electric field. However, without limiting to this, the draw-out of the raw material solution in the form of mist and the acceleration of the microparticles may be separately performed, as described in the second exemplary embodiment. Alternatively, the draw-out in the form of mist may be conducted without conducting the acceleration of the microparticles.

As illustrated in FIG. 15, in the thin film forming device 2 of the second exemplary embodiment, a draw-out electrode 112 fanned of a conductive material is provided in the vicinity of the raw material solution supply unit 50 configured to supply the raw material solution 62, and a draw-out power supply unit 114 configured to apply voltage between the draw-out electrode 112 and the raw material solution supply unit 50 is provided. Specifically, as illustrated in FIG. 16, the draw-out electrode 112 includes an electrode body 118 formed with a microparticle passage hole 116 below the front end of the solution outlet 58 at the front end of the nozzle 56, i.e. at a place spaced apart to the holding unit. The electrode body 118 is formed to cover at least the surrounding area of the nozzle 56.

Here, the electrode body 118 includes a lateral side portion 118A formed in a cylindrical shape to enclose the nozzle 56 and a part of the lateral side of the header unit 54, and a bottom side portion 118B connected to the lower end of the side surface portion 18A and formed with the microparticle passage hole 116 at the central portion thereof. Thus, the solution outlet 58 of the nozzle 56 is configured to face the processing space 53 through the microparticle passage hole 116 positioned just below the solution outlet 58. An insulation member 60 is interposed between the header unit 54 and the upper portion of the cylindrical lateral side portion 118A of the electrode body in such a manner that the insulation member 60, the header unit 54 and the cylindrical lateral side portion 118a of the electrode body are integrally attached to each other, and the header unit 54 and the draw-out electrode 112 form a single solution injection unit 120.

In addition, the lateral side portion 118A of the electrode body is attached and fixed to the ceiling portion of a processing container 4 through an insulation member 122. Here, the diameter H2 of the microparticle passage hole 116 is set to, for example, about 0.5 mm and the distance H3 between microparticle passage hole 116 and the solution outlet 58 is set to, for example, about 0.5 mm. Further, the height of the electrode body 118 is about 32 mm and the diameter is about 30 mm but these sizes are not particularly limited. The material of the draw-out electrode 112 is a conductive material and, for example, a metal such as aluminum or aluminum alloy may be used for the material. However, a highly corrosion-resistant resin as described above, for example, PEEK (trade mark) may be used.

The draw-out power supply unit 114 includes a draw-out power supply 124 and is configured to apply draw-out voltage between the header unit 54 and the draw-out electrode 112 through a wiring 126. Thus, large electric field is generated between the front end of the nozzle 56 of the header unit 54 and the bottom side portion 118B of the electrode body so that the raw material solution 62 is drawn out and dispersed from the solution outlet 58 through the microparticle passage hole 116. The draw-out power supply 124 is configured to be voltage-controllable and to be capable of outputting a voltage of up to 10 kV. The draw-out power supply 124 may be a type that applies, for example, a direct current voltage or a plus voltage and may a type that applies a alternating current voltage as long as it has a frequency that enables the dispersion of the raw material solution 62.

Also, a constant current circuit 128 is provided in the middle of the wiring 126 that connects the draw-out power supply 124 and the header unit 54 to keep the current flowing in the header unit 54 constant so that the dispersion amount of the raw material solution 62 from the nozzle 56 may be kept constant. In addition, the constant current circuit 128 is configured to be capable of control a current value in response to an instruction from the device control unit 80 so as to control the dispersion amount. Further, the constant current circuit 128 may be omitted.

Further, an acceleration power supply unit 130 configured to accelerate the microparticles of the raw material solution is connected between the draw-out electrode 112 and the holding unit 8. Specifically, the acceleration power supply unit 130 includes an acceleration power supply 132 and connected between the draw-out electrode 112 and the holding unit through wirings 126, 134. Thus, an electric field is generated between the draw-out electrode 112 and the holding unit 8 so that the microparticles entering into the processing space 53 through the microparticle passage hole 116 may be accelerated downwardly. The acceleration power supply 132 is configured to be voltage-controllable and to output a voltage of, for example, up to 20 kV. With this acceleration power supply 132, for example, a direct current voltage, a pulse voltage, or an alternating current voltage may be used. When a direct current voltage is used for the draw-out power supply 124 and the acceleration power supply 132, it is natural that they are connected so the polarities of them take the same direction.

In addition, the power unit for acceleration 130 may be omitted as long as it is possible to obtain sufficient velocity of the dispersed microparticles with the power supply for draw-out 24. Further, the distance between the lower end of the draw-out electrode 112 and the top end of the mounting table 10 which is the holding unit 8 is, for example, about 1 cm to 10 cm.

Next, descriptions will be made on the operation of the second exemplary embodiment of the second exemplary embodiment of thin film forming device configured as described above. Also in the second exemplary embodiment, film forming may be performed either under a reduced pressure atmosphere or an atmospheric pressure, and the basic operation of the second exemplary embodiment is the same as that of the first exemplary embodiment except the method of applying the voltage for draw-out.

In the second exemplary embodiment, when the voltage from the draw-out power supply 124 is applied between the header unit 54 and the draw-out electrode 112, a high electric field is generated between the front end of the nozzle 56 of the header unit 54 and the bottom surface portion 118B of the draw-out electrode 112, an electric field concentration occurs at the front end of the nozzle 56 and raw material solution 62 is drown out from the solution outlet 58 at the lower end of the nozzle 56 and dispersed, thereby being brought into the microparticle state. At this time, the voltage applied between the nozzle 56 and the draw-out electrode 112 is, for example, about 1 kV to about 10 kV. The dispersed microparticles pass through the microparticle passage hole 116 fanned at the electrode body bottom surface portion 118b while being dispersed, thereby being diffused into the processing space 53.

In addition, the microparticles passing the processing space 53 are further accelerated and diffused downward, i.e., toward the mounting table 10 side by the electric field generated by the voltage for acceleration applied between the draw-out electrode 112 and the mounting table 10 by the acceleration power supply unit 132 and attached to the surface of the substrate 6 on the mounting table 10, thereby forming a thin film. At this time, the voltage applied between the electrode draw-out 112 and the holding unit 8 is, for example, about 0 kV to 20 kV. Here, in order to control the thin film fanning rate, it may be sufficient if the draw-out voltage applied to the header unit 54 or draw-out current flowing therein is regulated.

Thus, the second exemplary embodiment may exhibit the same acting effects as those of the first exemplary embodiment described above with reference to, for example, FIG. 1. Of course, various modified examples described in the first and various modified embodiments illustrated in FIGS. 10 to 13 may also be applied to the second exemplary embodiment.

### Modified Embodiments

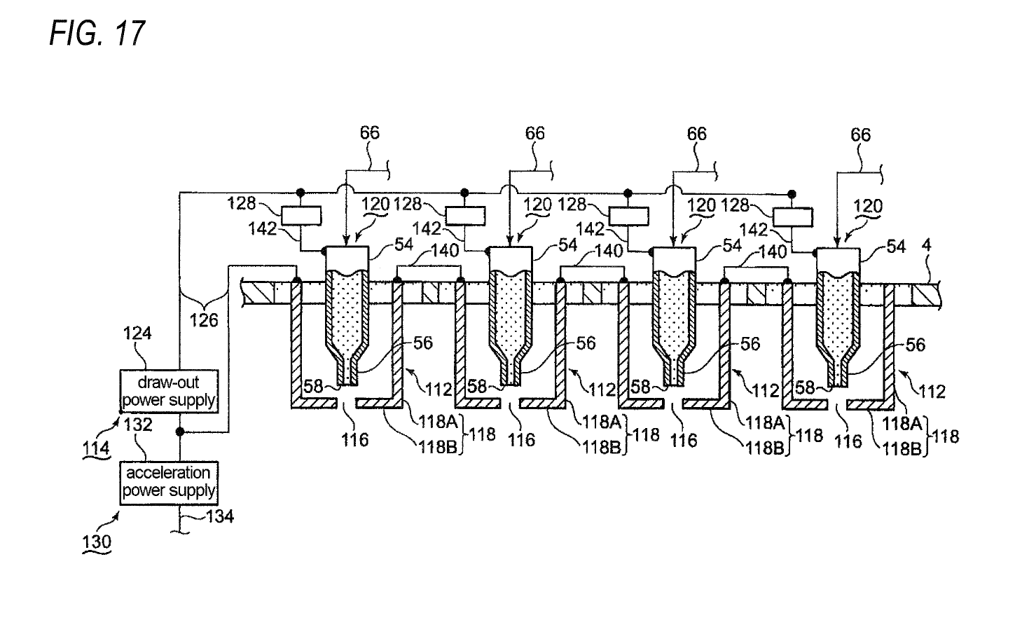

Next, descriptions will be made on modified examples of the raw material solution supply unit and the drawn-out electrode. FIG. 17 is a partial enlarged view illustrating a modified embodiment of the raw material solution supply unit. Also, the constitutional elements which are the same as those illustrated in FIGS. 15 and 16 are denoted by the same reference symbols.

In the second exemplary embodiment 2 as described above, only one solution injection unit 120 configured by the header unit 54 and the draw-out electrode 112 is installed on the ceiling portion of the processing container 4. However, without being limited thereto, a plurality of solution injection units may be installed as in the modified embodiment as illustrated in FIG. 17. Although four solution injection units 120 are provided in FIG. 17, the number is not especially limited.

As illustrated in FIG. 17, four injection units 120 are provided here each of which is configured by a header unit 54 and a draw-out electrode 112. In such a case, the individual draw-out electrodes 112, i.e., the electrode bodies 118 are commonly connected with each other by a wiring 140 and have the same potential. Further, the header units 54 are connected in parallel to each other by the wirings 142 extending from the wirings 126 and a constant current circuit 128 is provided in each wiring 142.

Also in such a case, the acting effects which are the same as those of the second exemplary embodiment described with reference to FIGS. 15 and 16 may be exhibited. Also, in this modified embodiment, the film forming rate may also be enhanced as much as the number of the header units 54 provided in this modified embodiment is increased. In addition, since this modified embodiment has a configuration in which the draw-out electrodes 112 are installed to correspond to the header units 54, respectively, the electric field may become easily generated at the front ends of the nozzles 56 as in the case in which a single solution injection unit 120 is provided as illustrated, even if the plurality of injection units 120 are provided. For this reason, although an excessively high voltage is required so as to draw out the raw material solution when a plurality of header units are installed in the thin film forming device according to the first exemplary embodiment, the present modified embodiment enables the raw material solution to be drawn out with the same voltage as that of the second exemplary embodiment (including a single solution injection unit). The plurality of solution injection units 120 may be installed in a linear arrangement or in a distributed arrangement within a region of a predetermined shape such as, for example, a circular shape or a rectangular shape.

Here, the electrode body 118 of each of the draw-out electrodes 112 is formed by a cylindrical lateral side portion 118A and a bottom side portion 118B but not limited thereto. For example, it is also possible to provide only the bottom side portion 118B of the electrode body while omitting the cylindrical lateral side portion 118A of the electrode body and to provide one sheet of conductive plate that interconnects four bottom side portions 118B transversely. In other words, it is possible to provide only one sheet of conductive plate and to form a microparticle passage hole 116 below and at a position corresponding to each of the solutions 58.

<Example of Photoelectric Conversion Element>

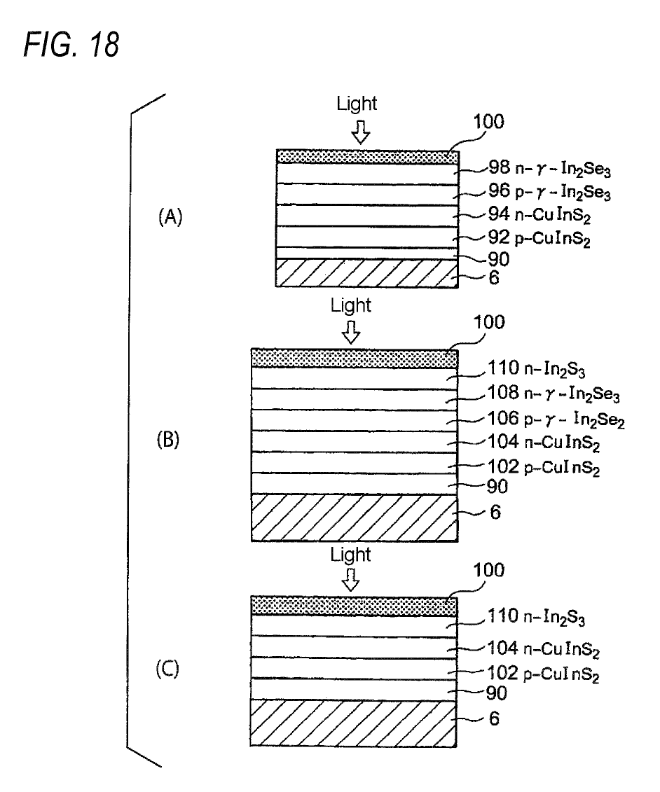

Next, descriptions will be made on a structure of a photoelectric conversion element using a semiconductor crystal thin film produced through the thin film forming methods as described above. FIG. 18 is a schematic cross-sectional view illustrating an example of a structure of a photoelectric conversion element. The photoelectric conversion element illustrated in FIG. 18A is effective as, for example, a solar cell. The photoelectric conversion element is entirely configured by forming a bottom electrode 90, a p-type CuInS₂ film 92, an n-type CuInS₂ film 94, a p-type γ-In₂Se₃ film 96, an n-type γ-In₂Se₃ film 98, and a transparent electrode 100 on a substrate 6 in this order. A bottom cell is configured by the films 92, 94 and a top cell is configured by the films 96, 98. As described above, the substrate 6 is made of, for example, a glass plate and the bottom electrode 90 is formed of, for example, molybdenum. In addition, the transparent electrode 100 is formed from zinc oxide ZnO or indium tin oxide (ITO).

Also, the photoelectric conversion element illustrated in FIG. 18B is effective as, for example, a solar cell. The photoelectric conversion element is entirely configured by fanning a bottom electrode 90, a p-type CuInS₂ film 102, an n-type CuInS₂ film 104, a p-type γ-In₂Se₃ film 106, an n-type γ-In₂Se₃ film 108, an n-type In₂S₃ film 110, and a transparent electrode 100 on the substrate 6 in this order. A bottom cell is configured by the films 102, 104 and a top cell is configured by the films 106 to 110. As described above, the substrate 6 is made of, for example, a glass plate and the bottom electrode 90 is formed of, for example, molybdenum. In addition, the transparent electrode 100 is formed from zinc oxide ZnO or indium tin oxide (ITO).

Also, the photoelectric conversion element as illustrated in FIG. 18C is effective as, for example, a solar cell. The photoelectric conversion element is entirely configured by forming a bottom electrode 90, a p-type CuInS₂ film 102, an n-type CuInS₂ film 104, an n-type In₂S₃ film 110, and a transparent electrode 100 on the substrate 6 in this order. As described above, the substrate 6 is made of, for example, a glass plate and the bottom electrode 90 is formed of, for example, molybdenum. In addition, the transparent electrode 100 is formed from zinc oxide ZnO or indium tin oxide (ITO).

In each of the above-described exemplary embodiments, the solvent forming a raw material solution is ethanol but is not limited to this. As for the solvent, for example, water, an alcohol containing ethanol or methanol, an organic solvent, an aromatic-based solvent, an alcohol-based solvent, an ether-based solvent, an ester-based solvent may be used.

Also, the thin films formed in each of the above-described exemplary embodiments are a CuInS₂ film and an In₂Se₃ film but are not limited to them. A formed thin film may be that formed of any one selected from a group including, for example, In_{0.5}Ga_{0.5}P, γ-In₂Se₃, In₂S₃, CuIn_{1-X}Ga_{X}S, GaAs, CdTe, CuInS₂, CuIn_{1-X}Ga_{X}Se, and Cu₂ZnSnS₄.

In particular, when an In₂S₃ film is formed as described above, the substrate temperature is in the range of 275° C. to 350° C., preferably in the range of 300° C. to 350° C. In addition, when a Cu₂ZnSnS₄ film is formed, the substrate temperature is in the range of 340° C. to 380° C., preferably in the range of 360° C. to 370° C.

Also, in the above-described exemplary embodiments, a header unit 54 of a raw material solution supply unit 50 is disposed at the upper side and a mounting table 10 (holding unit 8) in which a substrate 6 is held is disposed below the heater unit 54. However, since the raw material solution is dispersed by electric field regardless of gravity, the exemplary embodiments are not limited to this positional relationship. For example, the positional relationships described above may be disposed to be inversely opposed to each other in the vertical direction, to be inversely opposed to each other in the horizontal direction corresponding to a transverse direction, or to be opposed to each other to be inclined to a direction inclined to the vertical direction.

1. A thin film forming method comprising:
holding a processed object to be processed;
heating the processed object;
dispersing a raw material solution containing a plurality of elements by an electric field such that the raw material solution becomes microparticles in a processing space; and
causing the microparticles to be adhered to a surface of the processed object to form a thin film containing the plurality of elements.

2-5. (canceled)

6. The thin film forming method of claim 1, wherein the processing space is formed with an electric field intensity of 100 kV/m or more.

7. The thin film forming method of claim 1, wherein the thin film is a thin film of one selected from a group including In_{0.5}Ga_{0.5}P, γ-In₂Se₃, In₂S₃, CuIn_{1-X}Ga_{X}S, GaAs, CdTe, CuInS₂, CuIn_{1-X}Ga_{X}Se, and Cu₂ZnSnS₄.

8. The thin film forming method of claim 1, wherein the thin film is CuInS₂, the temperature of the processed object is in the range of 250° C. to 305° C., and the atomic ratio Cu/In in the raw material solution is in the range of 0.85 to 1.40.

9. The thin film forming method of claim 1, wherein the thin film contains In and Se, the temperature of the processed object is in the range of 235° C. to 280° C., and the atomic ratio Se/In in the raw material solution is not less than 1.

10. The thin film forming method of claim 1, wherein the thin film is In₂S₃, and the temperature of the processed object at the time of film forming is in the range of 275° C. to 350° C.

11. The thin film forming method of claim 1, wherein the thin film is Cu₂ZnSnS₄ and the temperature of the processed object is in the range of 340° C. to 380° C.

12. A thin film forming device comprising:
a raw material solution supply unit configured to supply a raw material solution containing a plurality of elements to a processing space;
a holding unit configured to hold a processed object to be processed;
a heating unit configured to heat the processed object; and
an electric field power supply unit configured to apply a voltage between the holding unit and the raw material solution supply unit to generate an electric field and to disperse the raw material solution such that the raw material solution becomes microparticles by the electric field, the microparticles being electrically charged by the electric field and adhered to a surface of the processed object to form the thin film containing the plurality of elements.

13-17. (canceled)

18. A thin film forming device comprising:
a raw material solution supply unit configured to supply a raw material solution containing a plurality of elements to a processing space;
a holding unit configured to hold a processed object to be processed;
a heating unit configured to heat the processed object;
a draw-out electrode installed in the vicinity of the raw material solution supply unit; and
a draw-out power supply unit configured to apply a voltage between the holding unit and the raw material solution supply unit to generate an electric field and to disperse the raw material solution such that the raw material solution becomes microparticles by the electric field, the microparticles being electrically charged by the electric field and adhered to a surface of the processed object to form a thin film containing the plurality of elements.

19. The thin film forming device of claim 18, wherein an acceleration power supply unit configured to accelerate the microparticles of the raw material solution is connected between the draw-out electrode and the holding unit.

20. The thin film forming device of claim 18, wherein the raw material solution supply unit includes a header unit configured to temporarily store the raw material solution and the header unit is provided with a nozzle having a solution outlet.

21. The thin film forming device of claim 20, wherein the draw-out electrode includes an electrode body which is formed with a microparticle passage hole located at a place spaced apart from a front end of the solution outlet toward the holding unit side.

22. The thin film forming device of claim 21, wherein the electrode body is formed to cover at least the surrounding of the nozzle.

23. The thin film forming device of claim 18, wherein the plurality of elements are mixed in the raw material solution.

24. The thin film forming device of claim 21, wherein a plurality of header units are provided and each of the plurality of header units is provided with the electrode body.

25. The thin film forming device of claim 24, wherein the header units are respectively configured to be supplied with raw materials which have different atomic ratios of the plurality of elements so as to change the conductivity type of the thin film.

26. The thin film forming device of claim 24, wherein the header units are respectively configured to be supplied with raw materials which have different atomic ratios of the plurality of elements so as to change the conductivity type of the thin film.

27. The thin film forming device of claim 24, wherein each of the electrode bodies are electrically connected with each other to have the same potential.

28. The thin film forming device of claim 24, wherein constant current circuits are provide to correspond to the header units, respectively.

29. The thin film forming device of claim 12, wherein raw material solution supply unit, the holding unit and the heating unit are accommodated within a processing container configured to be capable of being exhausted.

30. The thin film forming device of claim 12, further comprising:
a temperature measuring unit configured to the temperature of the object, and
a temperature control unit configured to control the temperature of the processed object based on an measurement value of the temperature measuring unit.

31. The thin film forming device of claim 12, wherein the holding unit and the raw material solution supply unit are configured to be capable of being moved relatively.

32. The thin film forming device of claim 12, wherein the thin film is a thin film of one selected from a group including In_{0.5}Ga_{0.5}P, γ-In₂Se₃, In₂S₃, CuIn_{1-X}Ga_{X}S, GaAs, CdTe, CuInS₂, CuIn_{1-X}Ga_{X}Se, and Cu₂ZnSnS₄.
